(19) United States
(12) Patent Application Publication
(10) Pub. No.: US 2006/0087224 A1
(43) Pub. Date: Apr. 27, 2006

(54) Organic electroluminescence light-emitting device

(75) Inventors: Masahiro Oki, Imabari-shi (JP); Yuji Yokomizo, Imabari-shi (JP); Yoshio Taniquti, Chuou, Ueda-shi (JP)

Correspondence Address: BANNER & WITCOFF, 1001 G STREET N W, SUITE 1100, WASHINGTON, DC, 20001, US

(73) Assignee: Harison Toshiba Lighting Corporation, Imabari-shi (JP)

(21) Appl. No.: 10/512,343

(22) PCT Filed: Apr. 24, 2003
(86) PCT No.: PCT/JP03/05281

§ 371 Date: Dec. 12, 2005

(30) Foreign Application Priority Data
Apr. 25, 2002 (JP) 2002-124673
Apr. 25, 2002 (JP) 2002-124950

(51) Int. Cl. H01J 1/62; H01J 63/04

(52) U.S. Cl. 313/504

(57) ABSTRACT

An organic electroluminescent light emitting device is provided with light emitting characteristics hardly varying with time. The light emitting device includes a non moisture permeable translucent substrate 11, a light emitting laminated body 13 provided on the translucent insulating substrate 11 including an organic EL light emitting layer 16, a first electrode layer 15 laminated thereon, and a second electrode layer 17.

The light emitting device further includes a non moisture permeable sealing wall 14, which is provided on the substrate 11 by forming a space covering the light emitting laminated body 13 without striding over the first and second electrode layers 15, 17 of the light emitting laminated body 13, and connecting terminals 23 which are provided by penetrating the sealing wall or the substrate to supply electric power to each electrode layers 15, 17 of the light emitting laminated body 13.

### TECHNICAL FIELD

The present invention relates to an organic electroluminescent light emitting device.

### BACKGROUND TECHNOLOGY OF THE INVENTION

Generally, an organic electroluminescent light emitting device is composed of a light emitting laminated body which consists of an organic material layer emitting electroluminescence (hereinafter referred to as “EL”) light and an electrode layer, and connecting terminals for supplying the electrode layer of the light emitting laminated body with electric energy.

Specifically, the light emitting laminated body uses a translucent glass plate as a substrate to pick up light emitted there from on the substrate side. On the glass substrate, a transparent anode layer, an organic EL light emitting material layer, and a cathode are laminated in this order. When the electric energy is supplied between the transparent anode layer and cathode layer, holes are injected into the organic EL light emitting material layer from the anode layer and electrons are injected from cathode layer. With recombination of the electrons and the holes in the organic EL light emitting material layer, fluorescence or phosphorescence light is emitted when an exciton loses energy. The light emitting laminated body thus emits the light.

The light emitting laminated body is attracting attention as a display device in the next generation as an alternative to liquid crystal display devices, because of such advantages as excellent visibility of the emitted light, easy to set a color of the emitted light, and low power consumption.

However, the light emitting laminated body is apt to absorb moisture in the air, because organic materials are contained in the organic EL layer. When the laminated body absorbs moisture, a non light emitting portion is formed by peeling off of the electrode layer from the organic EL layer, or by deterioration of the layer itself. Deterioration also takes place in light emitting characteristics with age such as decrease in light emitting luminance etc for example. Therefore, the EL laminated body is often separated from wet air by sealing a periphery of the substrate on which the EL laminated body is formed with a sealing cap or protection plate made of glass or metal.

In order to minimize the moisture intruding through the joint portion formed between the glass substrate on which the EL laminated body is formed and sealing cap made of glass or metal, it is ideal to joint them by welding to provide a non moisture permeable configuration. However, when the sealing cap made of metal or glass is welded to the glass substrate with, the joint portion should be heated to higher than the softening point of glass, for example, around 700° C., which varies depending on the kind of glass. The heating of the glass substrate at such high temperature brings other problems that the light luminance decreases by oxidation or decomposition of the organic material contained in the laminated layer forming the organic EL, or that non light emitting portions are formed.

Generally, a glass substrate and a sealing cap made of metal or glass are joined with an adhesive material in order to prevent heat application to the EL laminated body when sealing. Room temperature setting adhesive or UV cure adhesive composed of acrylic resin or epoxy resin has been used as an adhesive material, because the temperature for curing is low, and the moisture permeability is low after curing.

Also, in the organic electroluminescent light emitting device, the electric power is supplied to the light emitting laminated body through electrode terminals, which is composed of an electrically conductive film and is led out through the boundary area between the glass substrate and sealing cap.

Here, the adhesion between the substrate and the electric conductive film forming the electrode terminal is not sufficient if the electrode terminals are led out from the sealing portion of the light emitting laminated body. Thus, moisture intrudes through the boundary area and results in degradation of the light emitting element composed of the light emitting laminated body. Another cause of the degradation of the light emitting element is that the electrode terminal itself cannot provide perfect air tightness.

As described above, in conventional organic electroluminescent light emitting device, a substrate on which organic EL layer is formed and a sealing cap which is a protective plate made of glass or metal are joined with such adhesive as the UV cure adhesive striding over the electrically conductive film through which electric power is supplied to the EL laminated body from outside. However, with such a structure, it is difficult to effectively block the moisture intrusion through the boundary area between the substrate and electric conductive film or through the electric conductive film itself, and to prevent the variation of light emitting characteristics with time of the organic electroluminescent light emitting device.

It is therefore one of the objects of the present invention to effectively block the intrusion of moisture into the inside of the organic electroluminescent light emitting device from outside, and to provide the organic electroluminescent light emitting device with extremely small variation of light emitting characteristics with time.

### DISCLOSURE OF THE INVENTION

The organic electroluminescent light emitting device according to the present invention includes a translucent insulating substrate, a light emitting laminated body provided on the translucent insulating substrate including an organic EL light emitting layer and an electrode layer laminated thereon, a sealing cap joined to the translucent insulating substrate to form a space covering the light emitting laminated body, and electrical connecting terminals which penetrate the sealing cap or the translucent insulating substrate and supply electric power to the electrode layers included in the light emitting laminated body, wherein the electrical connecting terminals are led outside without passing through the joined portion between the translucent insulating substrate and the sealing cap.

Further, the organic electroluminescent light emitting device according to the present invention includes a translucent insulating substrate on the periphery of which a metal frame is joined, a light emitting laminated body composed of a first electrode layer, an organic EL light emitting layer, and a second electrode layer, which are laminated in this order, a sealing metal cap which is joined to the metal frame to form a space covering the light emitting laminated body, and electrical connecting terminals which penetrate the sealing cap or the translucent insulating substrate and supply electric power to each electrode layer of the light emitting laminated layer, wherein the electrical connecting terminals are led out without passing through the joined portion between the substrate and the sealing cap.

Further, the organic electroluminescent light emitting device according to the present invention includes non moisture permeable translucent substrate, a metal frame joined to the periphery of the translucent substrate, a pair of electrical connecting terminals penetrating the metal frame through an insulating material, a light emitting laminated body provided on one surface of the non moisture permeable translucent substrate, which is composed of an organic light emitting material layer and a pair of electrode layers laminated on both side of the organic light emitting material layer, an interconnection means, which connects each of the pair of electrode layers of the light emitting laminated body with each of the pair of electrically connecting terminals, and a metal sealing cap, which is joined to the metal frame in non moisture permeable manner on the side of the translucent substrate where the light emitting laminated body is provided, so as not to contact with the light emitting laminated body.

Further, the organic electroluminescent light emitting device according to the present invention includes a non moisture permeable translucent substrate on the periphery of which a metal frame is joined, one or plurality of electrical connecting terminals which penetrate the substrate or a joined portion between the substrate and the metal frame, a light emitting laminated body, which is provided on a surface of the substrate and is composed of an organic light emitting material layer and a pair of electrode layers laminated on both sides of the organic light emitting material layer, and a metal sealing cap which is joined to the metal frame in non moisture permeable manner on the surface of the substrate where the light emitting laminated body is provided, so as not to contact with the light emitting laminated body, wherein a chassis is formed with the substrate at its bottom and with a wall with the metal frame around the substrate, and wherein each of the pair of electrode layers forming the light emitting laminated body are respectively connected with the electrical connecting terminals.

Further, the organic electroluminescent light emitting device according to the present invention includes a non moisture permeable translucent substrate on the periphery of which a metal frame is joined, one or plurality of electrical connecting terminals which penetrate the substrate, a light emitting laminated body, which is provided on a surface of the substrate and is composed of an organic light emitting material layer and a pair of electrode layers laminated on both sides of the organic light emitting material layer those are, and a metal sealing cap which is joined to the metal frame with in non moisture permeable manner construction on the surface of the substrate where the light emitting laminated body is provided, so as not to contact with the light emitting laminated body, wherein a chassis is formed with the substrate at its bottom and with a wall with the metal frame around the substrate, and wherein one of the pair of electrode layers forming the light emitting laminated body is connected with the electrical connecting terminals, while the other electrode layers is connected with the metal frame.

Further, the organic electroluminescent light emitting device according to the present invention includes a metal substrate, one or a plurality of electrical connecting terminals which penetrate the metal substrate through an insulating material, an light emitting laminated body composed of an organic light emitting material layer and laminated electrode layers laminated thereon, and a non moisture permeable translucent plate, which is provided on a surface of the metal substrate where the light emitting laminated body is formed and to the periphery of which a metal frame is joined with non moisture permeable construction so as not to contact with the light emitting laminated body, wherein the electrode layer laminated on the organic light emitting material layer is connected to the electrical connecting terminal.

Further, the organic electroluminescent light emitting device according to the present invention includes a first and a second non moisture permeable translucent substrate with metal frame joined on the periphery, one or plurality of electrical connecting terminals penetrate the substrates through an insulating material, a light emitting laminated body composed of a pair of electrode layers and an organic light emitting material layer laminated between the pair of electrode layers, which are formed on one surface of the first and the second non moisture permeable substrates, and a metal sealing cap which joins the first and the second non moisture permeable substrates, so as to make surfaces of the first and the second non moisture permeable translucent substrate where the light emitting laminated body face with each other, wherein the electrode layers forming the light emitting laminated body are connected to each of the electrical connecting terminals respectively.

A method for manufacturing the organic electroluminescent light emitting device according to an embodiment of the present invention includes steps of joining a metal frame on a periphery of a non moisture permeable translucent substrate, fixing a plurality of electrically connecting terminals to the metal frame or the translucent substrate in a state electrically insulated there from, making the plurality of electrically connecting terminals penetrate through the metal frame or the translucent substrate, forming a light emitting laminated body on a surface of the substrate having an organic light emitting material layer and a plurality of electrode layers, connecting the plurality of electrode layers with the electrical connecting terminals or the metal frame, and joining a metal sealing cap or a metal protection plate to the surface of the translucent substrate with non moisture permeable construction on which the light emitting laminated body is formed so that the metal caps or the protection plate may not contact with the light emitting laminated body.

Further, a method for manufacturing the organic electroluminescent light emitting device according to another embodiment of the present invention includes steps of preparing a non moisture permeable translucent substrate having a metal frame joined on a peripheral portion, preparing a metal plate having one or a plurality of electrical connecting terminals which penetrate the metal plate through an insulating material, forming an light emitting laminated body composed of an organic light emitting material layer and electrode layers laminated thereon on one surface directly or through an insulating layer, connecting the electrode layers forming the light emitting laminated body with the electrical connecting terminals, and joining the metal frame joined to the non moisture permeable translucent substrate to a peripheral portion of the metal plate so as not to contact with the light emitting laminated body.

### BRIEF DESCRIPTION OF THE DRAWINGS

FIG. 1 is a perspective view with one portion cut showing an organic electroluminescent light emitting device according to an embodiment of the present invention.

FIG. 2 shows a cross section of an organic electroluminescent light emitting device cut along the line A-A′ in FIG. 1.

FIG. 3 is a drawing for explaining a method for manufacturing the organic electroluminescent light emitting device shown in FIG. 1.

FIG. 4 is a cross section showing an organic electroluminescent light emitting device shown in FIG. 1.

FIG. 5 is a cross section showing an organic electroluminescent light emitting device according to a second embodiment of the present invention.

FIG. 6 is an upper view for explaining an electrode lead out portion of the organic electroluminescent light emitting device shown in FIG. 5.

FIG. 7 is another upper view for explaining the electrode lead out portion of the organic electroluminescent light emitting device shown in FIG. 5.

FIG. 8 is a cross section showing an organic electroluminescent light emitting device shown in FIG. 5.

FIG. 9 is a cross section showing an organic electroluminescent light emitting device according to a third embodiment of the present invention.

FIG. 10 is a cross section showing a modification to the organic electroluminescent light emitting device shown in FIG. 9.

FIG. 11 is a cross section showing another modification to the organic electroluminescent light emitting device shown in FIG. 9.

FIG. 12 is a perspective view with one portion cut showing an organic electroluminescent light emitting device according to a fourth embodiment of the present invention.

FIG. 13 is a cross section of the organic electroluminescent light emitting device cut along the line I-I shown in FIG. 12.

FIG. 14 is a drawing for explaining a method for manufacturing the organic electroluminescent light emitting device shown in FIG. 12.

FIG. 15 is a cross section showing a modified example of the organic electroluminescent light emitting device shown in FIG. 12 and FIG. 13.

FIG. 16 is a cross section showing another modification of the organic electroluminescent light emitting device shown in FIG. 15.

FIG. 17 is a drawing for explaining an example of a mechanical joining method of a metal sealing cap and a metal frame.

FIG. 18 is a drawing for explaining a further different example of a method for joining the metal sealing cap to the metal frame in the manufacturing of the organic electroluminescent light emitting device shown in FIG. 17.

FIG. 19 is a drawing for explaining a further different example of a joining method of the metal sealing cap to the metal frame.

FIG. 20 is a perspective view, with a part is cut, showing the fifth embodiment of the organic electroluminescent light emitting device according to the present invention.

FIG. 21 is a drawing for explaining a method for manufacturing the organic electroluminescent light emitting device shown in FIG. 20.

FIG. 22 is a cross section showing a further different modification to the embodiment of the organic electroluminescent light emitting device according to the present invention.

FIG. 23 is a cross section showing a further different modification to the embodiment of the organic electroluminescent light emitting device according to the present invention.

FIG. 24 is a cross section showing a further different modification to the embodiment of the organic electroluminescent light emitting device according to the present invention.

FIG. 25 is a cross section showing a further different modification to the embodiment of the organic electroluminescent light emitting device according to the present invention.

FIG. 26 is a cross section showing a further different modification to the embodiment of the organic electroluminescent light emitting device of the present invention.

FIG. 27 is a cross section showing a further different modification to the embodiment of the organic electroluminescent light emitting device of the present invention.

FIG. 28 is a cross section showing a further different modification to the embodiment of the organic electroluminescent light emitting device of the present invention.

FIG. 29 is a drawing for explaining other manufacturing method of the organic electroluminescent light emitting device according to other embodiment of the present invention.

FIG. 30 is a cross section showing an organic electroluminescent light emitting device according to other embodiment of the present invention.

FIG. 31 is a cross section showing an organic electroluminescent light emitting device according to other embodiment of the present invention.

FIG. 32 is a cross section showing an organic electroluminescent light emitting device according to other embodiment of the present invention.

### DETAILED DESCRIPTION OF THE INVENTION

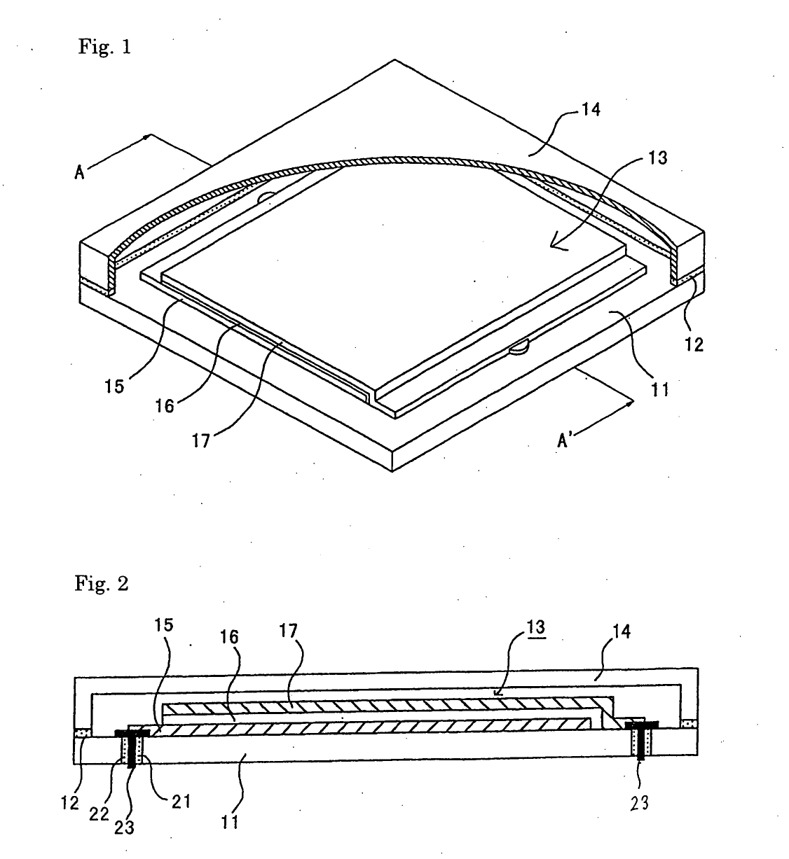

An organic electroluminescent light emitting device and the manufacturing method according to an embodiment of the present invention is explained using the accompanying figures. FIG. 1 is a perspective view with one portion cut showing a construction of an organic electroluminescent light emitting device according to an embodiment of the present invention. FIG. 2 is a cross section cut along the A-A′ line in FIG. 1.

The organic electroluminescent light emitting device shown in FIG. 1 and FIG. 2 is composed of a substrate 11, an light emitting laminated body 13 formed on one surface of the substrate 11, and a sealing cap 14. The substrate 11 is a non moisture permeable insulating translucent plate, such as a glass plate, for example. The light emitting laminated body 13 is composed of an organic EL light emitting material layer 16 and two electrode layers 15 and 17. On the substrate 11, two electrically connecting terminals (hereinafter referred to as connecting terminals) 23 are provided, which penetrate the substrate 11. A sealing cap 14 is joined to the surface of the substrate 11, on which the light emitting laminated body 13 is formed, in non moisture permeable manner using an adhesive 12. The sealing cap 14 is provided so as not to contact with the light emitting laminated body 13.

In order to bring light emitted from the light emitting laminated body 13 out of the light emitting device, the electrode layer 15 and 17 are made translucent. The electrode layers 15 and 17 of the light emitting laminated body 13 contact with the connecting terminals 23 respectively for electrical connection.

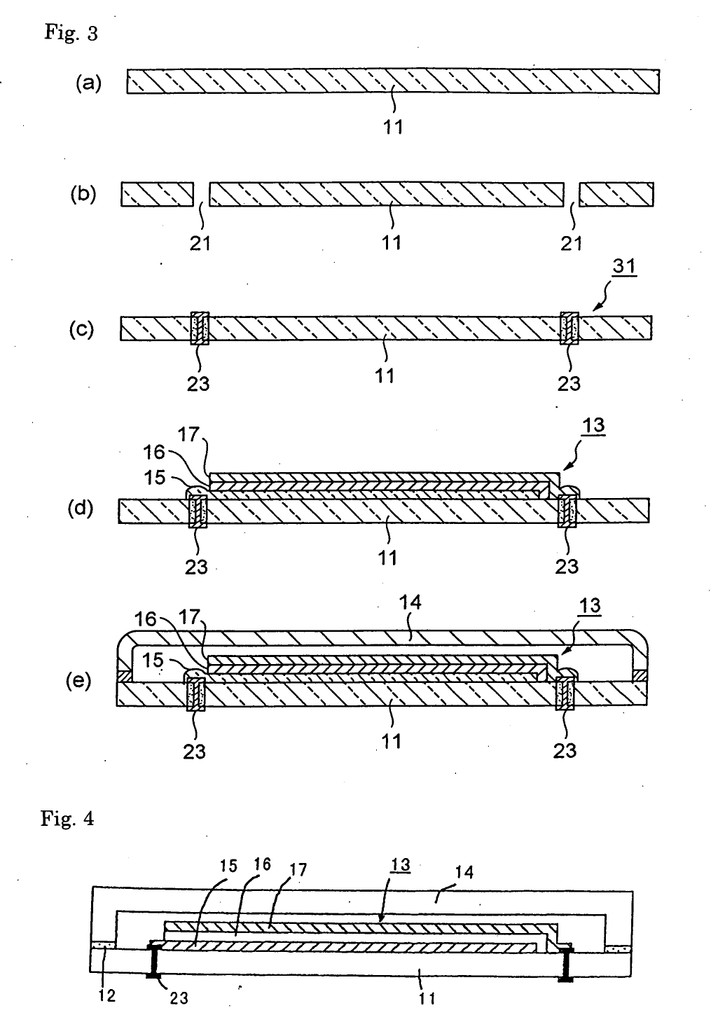

FIG. 3 is a drawing for explaining a method for manufacturing the organic electroluminescent light emitting device shown in FIG. 1. First, the substrate 11 shown in FIG. 3(a) is prepared. As the substrate 11, a glass plate was used. Next, holes 21 for receiving the connecting terminals are formed on the substrate 11 as shown in FIG. 3(b). As shown in FIG. 3(c), connecting terminals 23 made of electrically conductive material such as metal, for example, are fixed in the hole 21 provided on the substrate 11 using adhesive 22. For the adhesive 22, inorganic adhesive or a thermosetting organic adhesive can be used. Here, the substrate 11 on which connecting terminals 23 are provided is called as a light emitting element substrate 31.

Because the light emitting element substrate 31 is made before the light emitting laminated body 13 is formed, the substrate 11 and the connecting terminals 23 can be joined at high temperature in non moisture permeable manner. In the case of the organic electroluminescent light emitting device shown in FIG. 1, the substrate 11 and the connecting terminal 23 are joined in non moisture permeable manner by using such an inorganic adhesive 22 as frit glass or thermosetting adhesive that cures at rather high temperature.

Next, light emitting laminated body 13 is formed on one surface of the substrate 11 by laminating a translucent electrode layer 15, an organic EL light emitting material layer 16, and electrode layer 17 in this order. Each of the translucent electrode layers 15 and 17 are formed so as to contact with each connecting terminals 23 for electrical connection.

As shown in FIG. 3(e), a sealing cap 14 made of metal, for example, is provided on the surface of the light emitting element substrate 31 on which the light emitting laminated body is formed. The sealing cap 14 is arranged so as not to contact with the light emitting laminated body 13. The sealing cap 14 is joined to the glass plate 11 at its peripheries in non moisture permeable manner. That is, the sealing cap 14 and the glass substrate 11 are joined at a low temperature in a short time by using epoxy resin or cyanoacrylate group adhesive which cures at low temperature.

The organic electroluminescent light emitting device manufactured in this way has the following advantages.

(1) The translucent electrode layers 15 and 17 forming the light emitting laminated body 13 are connected electrically with each of the connecting terminals 23 penetrating the substrate 11, without passing through a joint portion between substrate 11 and sealing cap 14. That is, because the substrate 11 and the sealing cap 14 are joined directly without any electrically conducting thin film formed, intervening there between, on the substrate 11 by evaporation or sputtering, the mutual adhesion becomes stronger. Therefore, the moisture and oxygen intruding through the joint portion between the substrate 11 and the sealing cap 14 or through the electric conductive layer itself of the thin film can be minimized.

With this effect, variation of the light emitting characteristics of the organic electroluminescent light emitting device with time decreases, and thus the life of the light emitting device can be made longer.

(2) Further, because the translucent electrode layers 15 and 17 are not led out through the joint portion between the substrate 11 and the sealing cap 14, the heat generated for joining the substrate 11 and the sealing cap 14 is not conducted to light emitting laminated body 13 through the translucent electrode layers 15 and 17. Therefore, the light emitting laminated body 13 is not affected by a violent heat stress. As a result, the organic electroluminescent light emitting device thus manufactured according to the present invention has also good initial light emitting characteristics.

Various modifications are applicable about the embodiment of the organic electroluminescent light emitting device mentioned above. For example, as a substrate 11, it is not limited to a glass plate, but a resin plate etc. coated with a thin film of non moisture permeable nature. That is, if it is a translucent plate having non moisture permeability and insulating property, the material is not limited to the materials mentioned above.

Further, in the organic electroluminescent light emitting device shown in FIG. 2, the substrate 11 and the connecting terminal 23 are fixed using adhesive 22, however, they can be joined directly without using the adhesive 22.

FIG. 4 is a cross section of an organic electroluminescent light emitting device showing such a modification. In the device, a glass is used as a substrate 11, which is partially molten. The connecting terminals 23 are penetrating this portion. The connecting terminals 23 are then fixed on the substrate 11 by solidifying the glass. In this case, it is desirable to select the combination that the thermal expansion coefficient of the glass constituting the substrate 11 and that of the connecting terminals 23 are as close as possible.

Further, when joining the substrate 11 and the sealing cap 14, it is possible to increase the contact area by making one joining surface to be a convex one and the other surface to be a concave one corresponding to the convex surface.

Further, it is desirable to make the space formed by the substrate 11 and the sealing cap 14 to be a vacuum space or a space filled with an,inert gas. For this purpose, joining of the substrate 11 and the sealing cap 14 is performed in vacuum or in an inert gas atmosphere.

Next, the light emitting laminated body can be manufactured by a method well known to the public. The materials composing the organic EL emitting laminated body are described in detail in “Problems to be solved and Strategy for Practical Use of Organic LED Elements” (Bunshin Publishing Co. 1999), “Functional Organic Materials for Optical and Electronic Use Handbook” (Asakura Book Store 1997) and other publications. A typical method for manufacturing the light emitting laminated body is explained below.

It is preferable to build a light emitting laminated body 13 by laminating the translucent electrode layer 15, the organic EL light emitting material layer 16, and the electrode layer 17 in this order, on one surface of the substrate 11 as mentioned above.

It is preferable to form the translucent anode layer 15 with a metal having a high work function (4 eV or higher), electrically conductive compound or a mixture thereof. As a typical example of the material composing the translucent anode layer 15, ITO (indium oxide doped with tin) and IZO (oxide of indium and zinc) are used.

Examples for a method for forming a translucent anode layer 15 are vacuum evaporation method, DC sputter method, RF sputter method, spin coat method, cast method, and LB method.

The transmittance for visible light of the translucent electrode 15 is preferably 70% or higher and it is more preferable to be 80%, 90% or higher is more. The transmittance for visible light can be adjusted by selecting a material forming the electrode layer, or by adjusting the thickness of the electrode layer. The thickness of the translucent anode layer is in general 1 μm or less, and it is more preferable that the thickness is 200 nm or less. Several hundred Ω/sq. or lower is preferable for the resistance of the translucent anode layer 15.

The organic EL light emitting material layer 16 is made of an organic light emitting material or of an organic material, which is composed of an organic material having carrier transportability (by a hole, an electron or both) (hereinafter referred to as host material) added with a small amount of organic light emitting material. By selecting organic light emitting material used for organic EL emitting material layer, a color of the light emitted from the organic electroluminescent light emitting device can be easily selected.

Materials which are excellent in forming a good film with excellent stability are selected for the organic EL light emitting material layer 16 of the light emitting laminated body. As such materials, a metal complex represented by Alq3 (tris(8-hydroxyquinolinat)aluminum), polyphenylenevinylene (PPV) derivative, polyfluorene derivative etc. are used. As organic light emitting material used with host material, a fluorescent dye which is difficult to form a stable thin film by the dye itself can be used beside the above mentioned organic light emitting material because the adding amount is small. As examples of fluorescent dye, coumalin, DCM derivative, quinacridone, perylene, and rubrene are used. As host materials, Alq3, TPD(triphenyldiamine), electron transportable oxadiazole derivative (PBD), polycarbonate series copolymer, and polyvinylcarbazole etc. are used. Further, a small amount of organic light emitting material such as fluorescent dye can be added for adjusting the luminescence color when preparing organic EL emitting material layer with organic light emitting material as mentioned above.

As the method for forming an organic EL light emitting layer 16, vacuum deposition method, spins coat method, cast method, and LB method are applicable. To realize a practical luminescent efficiency, the organic EL light emitting material layer 16 preferably has a thickness of 200 nm or less.

It is preferable to build the cathode layer 17 with a metal of low work function (4 eV or lower), alloy composition, electrically conductive compound, or a mixture thereof. As a typical material composing the cathode 17, Al, Ti, In, Na, K, Mg, Li, rare earth metal, alloy compositions such as Na—K alloy, Mg—Ag alloy, Mg—Cu alloy, Al—Li alloy are used.

The thickness of the cathode layer 17 is in general 1 μm or less, and more preferably 200 nm or less. The resistance of the cathode layer is preferably several hundred Ω/sq or lower. When forming the cathode layer 17, sometimes the molecules of the material composing the cathode layer 17 collide with the light emitting laminated body 13 to damage the light emitting layer. In order to protect the light emitting laminated body 13 from being damage, a buffer layer (not illustrated) can be provided on the surface of the cathode layer 17 on the organic EL emitting material layer 13 side. As an example of material for the buffer layer, an acetylacetnat complex or its derivative is used. It is preferable that the center metal of the acetylacetnat complex is an alkali metal, alkali earth metal, or a transition metal. As a material for the buffer layer, bisacetylacetnate nickel is especially preferable. The buffer layer is disclosed in for example, Japanese Patent laid open No. 2001-176670.

Further, a hole transportation layer (not illustrated) can be provided between the organic EL light emitting material layer 16 and anode layer 15, and an electron transportation layer (not illustrated) can be provided between the organic EL emitting material layer and the cathode layer 17, in order to increase the injection efficiency of carriers (holes and electrons) into the light emitting layer.

As a typical example of materials forming the hole transportation layer, a hole transportation material such as tetraarylbenzidine compound, aromatic amines, pyrazoline derivatives, and triphenylene derivatives are known. As a preferable example of the hole transportation material, tetraphenyldiamine (TPD) is known. The thickness of the hole transportation layer is preferably in the range from 2 to 200 nm. The hole transportation layer can be prepared with a similar method to the method for forming the organic EL emitting material layer.

It is desirable to add the electron receptive acceptors to the hole transportation material for improving hole transportability such as hole mobility. As the electron receptive acceptor, metal halide, Lewis acid, and organic acid, are known. Adding the electron receptive acceptor to the hole transportation layer is described in Japanese Patent laid open gazette No. H11-283750. When producing the hole transportation layer with the hole transportation material added with electron receptive material, it is desirable that the thickness of the hole transportation layer is in the range from 2 to 5000 nm.

As a typical example of material for the electron transportation layer, nitro substitute fluorene derivative, diphenylquinone derivative, thiopyrandioxide derivative, heterocyclic tetracarboxylic acid anhydride such as naphthalene pyrilene, carbodiimide, Fluorenyliden Methane derivative anthraquinodimethane and anthrone derivative, oxadiazole derivative, quinoline derivative, quinoxaline derivative, perylene derivative, pyridine derivative, pyrimidine derivative, and stilbene derivative are known. Also, alumiquinolinol complex such as tris(8-hydroxyquinoline) aluminum (Alq) can be used. The thickness of the electron transportation layer is preferable in the range of 5 to 300 nm. The electron transportation layer can be produced by a similar method to the method for forming the organic EL light emitting material layer 16.

The connecting terminals 23 for supplying electric energy to each electrode layers 15, 17 of the light emitting laminated body 13 can be provided in the same way as in the EL emitting device well-known to the public or in an electric bulb having a filament.

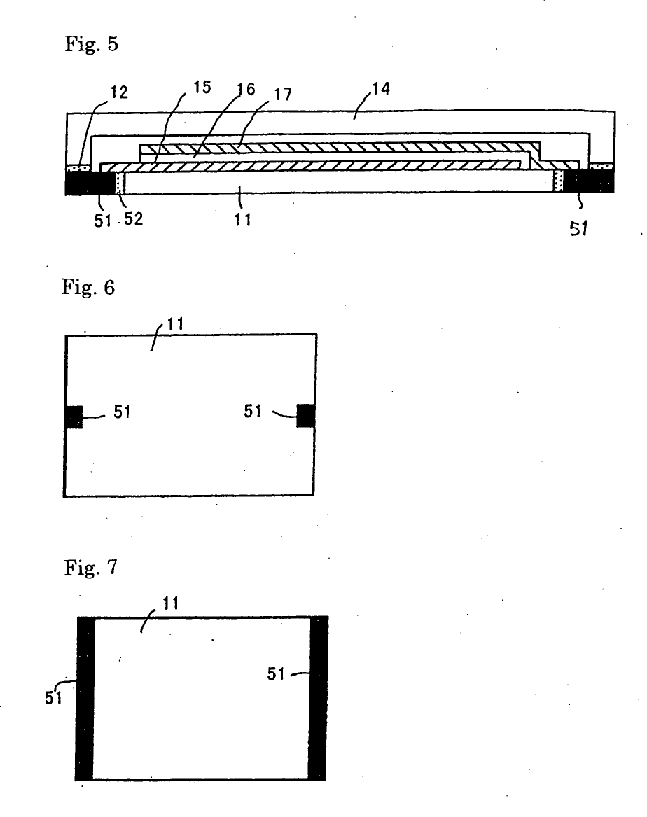

Next, the second embodiment of the present invention is explained referring to FIG. 5 to FIG. 8. In the present embodiment, terminals are lead out externally by a metal plate 51 provided adjacent to the substrate 11 as shown in FIG. 5, while in the embodiment mentioned above, the terminals are lead out externally by connecting terminals 23 made of metal and fixed to the substrate 11. That is, a pair of metal substrates 51, 51 is joined to the substrate 11 at opposite edge portions thereof. On the surface of the substrate of the substrate 11, a translucent electrode 15, an organic EL light emitting material layer 16, and an electrode layer 17 are formed to form the light emitting laminated body 13. Each end of the positive and the negative electrode layers 15 and 17 are extended so as to contact with the metal substrates 51, 51, which act as electrical connecting terminals. A sealing cap 14 is so joined to the substrate 11 with adhesive 12 that it may not contact with the light emitting laminated body 13 including the electrode layers 15, 17, where the organic electroluminescent light emitting device is formed.

It is desirable for the material of the metal substrate 51, which acts as a connection terminal, to be a metal having a thermal expansion coefficient close to that of the substrate 11, to have a good wet ability with the substrate 11. When a glass plate is used as the substrate 11, it is desirable that the both are joined by welding. As materials composing the metal substrate 51, Fe, Fe‘Ni alloy, Fe—Ni—Cr alloy, and Fe—Ni—Co alloy are used. It is desirable that a copper film is formed on the surface of the metal plate made of these materials. Further, glass and metal can be welded by using powder glass (also called as frit glass). The method for joining glass with metal is described in detail in “Glass Engineering Handbook” (Asakura Book Publishing Co. Ltd. 1999).

A shape of the metal plate 51 which acts as connecting terminals may be preferably formed on a part of the end portion of the substrate 11 as shown in FIG. 6, or a metal plate 51 may be joined to the entire length of the opposing edges of the substrate 11 as shown in FIG. 7.

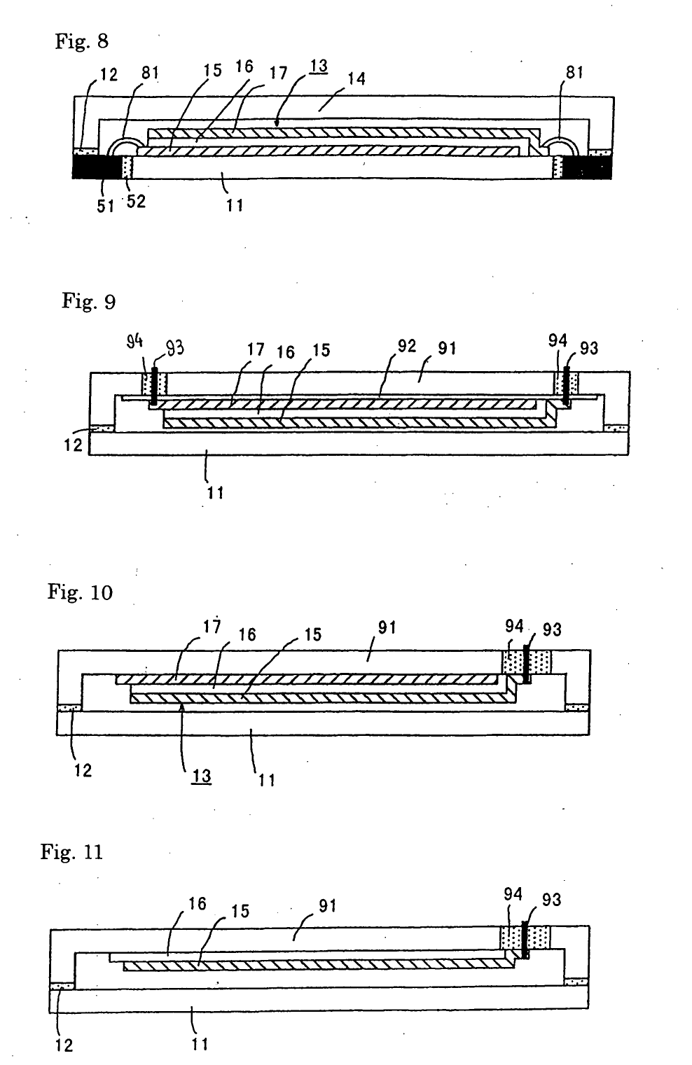

Although the electrodes are lead out from the light emitting laminated body 13 through the electrode layers 15, 17 which are electrically conductive thin film, as shown in FIG. 5, the electrode layers 15, 17 can be connected with the metal plate 51 by wire bonding. That is, the electrical conductive thin film electrodes 15, 17 of the light emitting laminated body 13 are connected with the metal plate 51, 51 by wire bonding 81, 81 to form electrodes as shown in FIG. 8. With this method, the moisture permeability can be decreased and the degradation of the device can be prevented, because the electrode layers 15, 17 are led out without passing through the joined portion between the substrate 11 and the sealing cap 14.

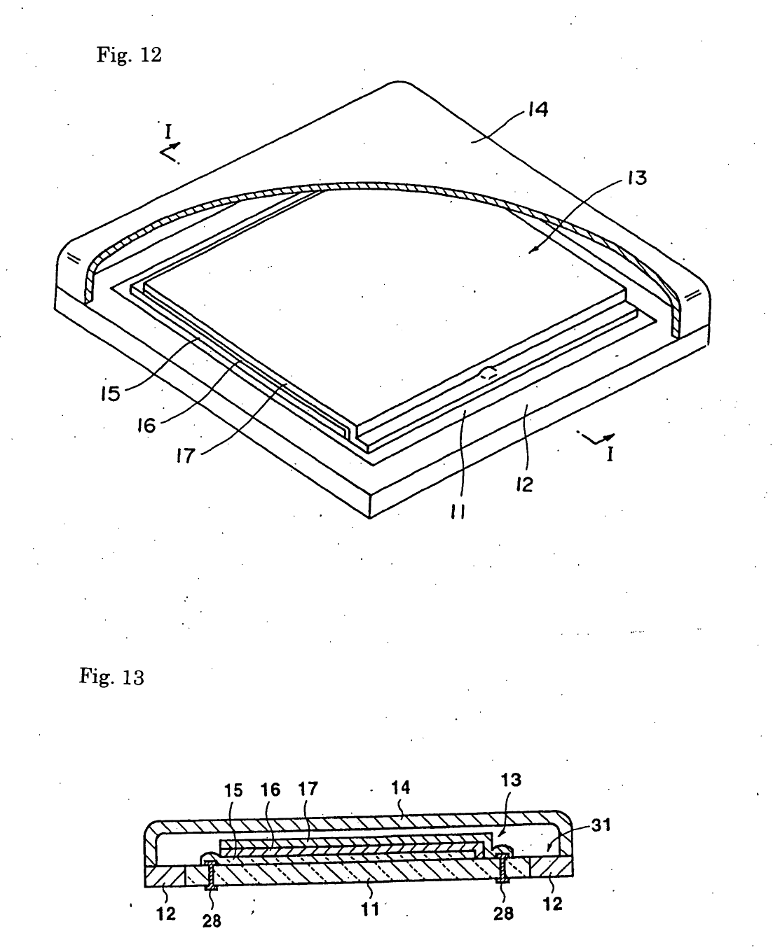

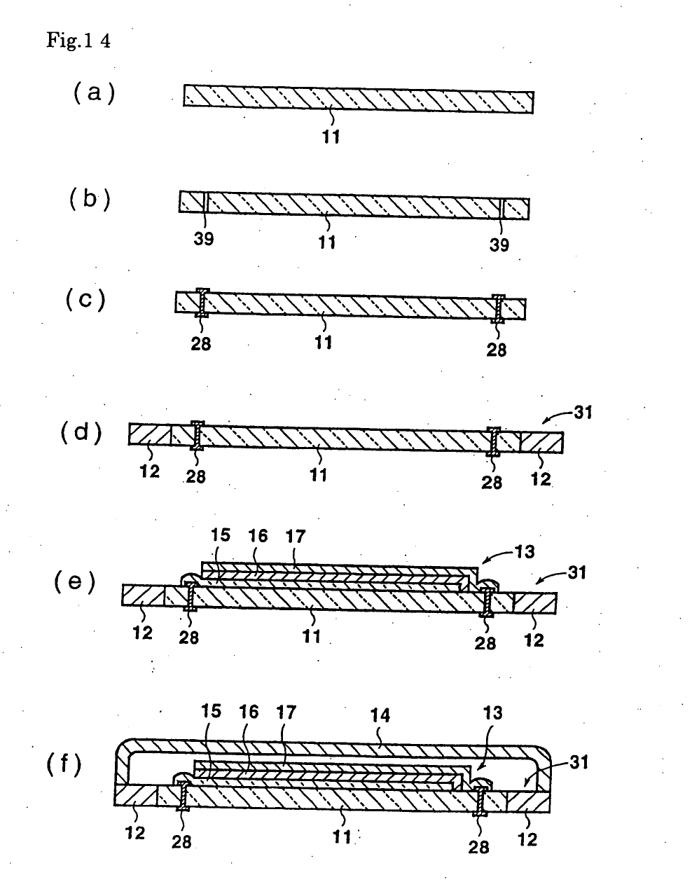

Next, the third embodiment of the present invention is explained with reference to FIG. 9 to FIG. 11.

In this embodiment, an electrically conductive material is used as a part of materials composing the chassis of the organic electroluminescent light emitting device. That is, an electrically conductive substrate 91 is used forming a chassis made of metal, for example, with an open lower end. On an insulating layer 92 formed on a ceiling of the electrically conductive chassis substrate, a light emitting laminated body 13 is formed, which is composed of an electrode layer 17, an organic EL light emitting material layer 16, and a translucent electrode layer 15. The lower open end of the electrically conductive chassis substrate 91 is sealed with a translucent substrate 11. That is, the open end of the electrically conductive chassis substrate 91 is sealed with a translucent substrate 11 using an adhesive 12. The translucent electrode layers 15 and 17 are connected with electrical connecting terminals 93, 93, made of metal, which penetrate the insulating layer 92 and the ceiling portion of the chassis substrate 91. The electrical connecting terminals 93, 93 are fixed in a through hole provided on the ceiling portion of the chassis substrate 91 using insulating adhesive 94, 94. As an insulating layer 92 formed on the ceiling of the chassis substrate 91, a resin layer coated on the surface of the chassis substrate 91 or a plastic film may be used.

FIG. 10 is a cross section showing a modified embodiment of the organic electroluminescent light emitting device shown in FIG. 9. In the light emitting device shown in FIG. 9, the electrode layers 15, 17 were insulated by the insulating layer 92 from chassis substrate 91. However, in the present modified embodiment, the chassis substrate 91 itself serves as an electrical connecting terminal by forming the electrode layer 17 directly on the chassis substrate 91. On the other hand, the translucent electrode layer 15 is connected with the electrically conductive terminal 93 fixed on the chassis substrate 91 with an insulating adhesive 94 as shown in FIG. 9. With such configuration, the insulating layer 92 shown in FIG. 9 is omitted.

Further, when an electrically conductive substrate is used for a substrate of the light emitting laminated body 13, the substrate itself can serve as the electrode layer. That is, the organic EL light emitting material layer 16 is formed directly on the electrically conductive chassis substrate 91, without the electrode layer 17 shown in FIG. 9 or in FIG. 10, and the translucent electrode layer 15 is formed on the layer 16. With the configuration, the organic electroluminescent light emitting device can be made with less number of films.

In the embodiments mentioned above, the organic EL emitting laminated body has a three layer construction composed of an electrode layer, an organic EL emitting material layer, and a translucent electrode layer. However, it is needless to say that the hole transportation layer or the electron transportation layer can be provided between the electrode layer or the translucent electrode layer and the organic EL emitting material layer. Further, in the above embodiments, although the organic EL emitting laminated body was sealed by the metal sealing cap or by the metal chassis, the entire structure can be built with a non moisture permeable insulating translucent plate. In this case, both of the two electrode layers are translucent electrode layers. Further, an opaque non moisture permeable insulating substrate can be used instead of a translucent insulating plate, where a translucent plate may be embedded in a part of the opaque substrate to serve as a light guide window.

As mentioned above, the organic electroluminescent light emitting device is provided having a structure, in which the thin film electrode layer forming the electrical connecting terminal led out of the light emitting laminated body does not cross the joined portion of the substrate to the chassis surrounding the organic EL emitting laminated body. Thus the moisture resistance of the device is improved and luminescence characteristics of the device seldom vary with time.

FIG. 12 to FIG. 14 are drawings showing an organic electroluminescent light emitting device and a method for manufacturing it according to the fourth embodiment of the present invention.

FIG. 12 is a perspective view with one portion cut showing a structure of the organic electroluminescent light emitting device. FIG. 13 is a cross section of the organic electroluminescent light emitting device along the line I-I in FIG. 12. Here, in these embodiments, the same parts as those in FIG. 1 to FIG. 3 are assigned with the same symbols to avoid duplicated explanations as much as possible.

The organic electroluminescent light emitting device according to the present embodiment differs from that of the first embodiment in that a non moisture permeable translucent substrate 11 is used, on the periphery of which a metal frame 12 is joined in non moisture permeable way. On a surface of the substrate 11, an light emitting laminated body 13 is formed, around which a metal sealing cap 14 is provided so as not to contact with the light emitting laminated body 13. The light emitting laminated body 13 is composed of an organic light emitting material layer 16 and two electrode layers 15 and 17 which hold 16 there between. Each end of the electrode layers 15 and 17 contacts with two electrical connecting terminals 28 respectively for electrical connection, which are fixed to the substrate 11 by penetrating the substrate 11. Here, the substrate 11 having metal frame 12 and two connecting terminals 28 is called light emitting element substrate 31 as mentioned above.

FIG. 14 is a drawing for explaining a method for manufacturing the organic electroluminescent light emitting device shown in FIG. 12 and FIG. 13. First, a glass plate is prepared as a substrate 11 shown in FIG. 14(a). Next, through holes 39 for arranging connecting terminals 28 are provided on substrate 11 as shown in FIG. 14(b). Connecting terminals 28 composed of electrically conductive material such as metal are welded in the through holes 39 in the substrate 11 as shown in FIG. 14(c). A metal frame 12 is joined in non moisture permeable way on the periphery of substrate 11 as shown in FIG. 14(d) The substrate 11 and the metal frame 12 can be joined in non moisture permeable way at a high temperature, because the light emitting laminated body 13 described later has not been formed yet. Here, the substrate 11 and the metal frame 12 are joined by welding. In this way, the substrate composed of a substrate 11, the metal frame 12 and the connecting terminals 28 is prepared.

In the next, the light emitting laminated body 13 is formed by laminating a translucent anode layer 15, an organic light emitting material layer 16, and a cathode layer 17 in this order on the surface of the substrate 11 of light emitting element substrate 31 as shown in FIG. 14(e). Each of the translucent anode layer 15 and cathode layer 17 are made contact with each connecting terminal 28 for electrical connection.

Further, a metal sealing cap 14 is arranged on the surface of the light emitting element substrate 31, on which the light emitting laminated body 13 is formed, so as not to contact with the light emitting laminated body 13 at the inner surface of the metal sealing cap 14, as shown in FIG. 14(f). Then, the periphery of the metal sealing cap 14 is joined to the metal frame 12 in non moisture permeable way. Here, the metal sealing cap 14 and the metal frame 12 are joined to each other in a short time at a low temperature by welding using ultrasonic energy for example.

The method of joining a metal such as the metal sealing cap 14 to a metal such as the metal frame 12 at low temperature in a short time is known. As examples of method for joining the metal sealing cap to the metal frame, ultrasonic welding, pressure welding, resistance welding, HF induction welding, HF resistance welding etc. are known. The methods for welding are described in detail in “The Metal Handbook” 4th revised edition (Maruzen Co. Ltd.). Further, the joining of the metal sealing cap to the metal frame can be performed by such a mechanical joining as fitting one into another without gap. An actual example of mechanical joining is described later. By joining the metal sealing cap 14 to the metal frame 12 in a short time and at a low temperature in non moisture permeable way, they can be joined directly, because there is no electrode layer at the joining portion of the metal sealing cap to the metal frame different from the conventional one. As a result, moisture intruding through the joining portion can be made less, so that the organic EL light emitting device can be obtained, which hardly changes its luminescence characteristics.

As just described, by sealing the light emitting laminated body using a joining the metal to the metal at low temperature in a short time, the following merits can be obtained.
(1) Because there is no electrode layer at the joining portion of the metal sealing cap to the metal frame, the both parts can be joined directly. Therefore, the moisture and oxygen intruding through the joint portion between the substrate and the sealing cap can be minimized compared with the joining with an adhesive.

With this effect, variation of the light emitting characteristics of the organic electroluminescent light emitting device with time decreases, and thus the life of the light emitting device can be made longer.
(2) Heating of the light emitting laminated body during the joining process of the substrate to the sealing cap can be prevented and thus influence of thermal stress can be prevented. Therefore, the initial luminescence characteristics of the organic electroluminescent light emitting device are excellent.
(3) Neither curing time of adhesive nor protrusion amount of adhesive must be controlled in detail during the manufacturing process of the organic electroluminescent light emitting device, because adhesive is not used for joining the substrate to the sealing cap, as in the conventional case.
(4) Because UV cure adhesive is not used for joining the substrate to the sealing cap, the degradation of the light emitting laminated body, owing to the energy of ultraviolet ray illuminated while joining process, is prevented.

Further, when joining the metal sealing cap to the metal frame, the joining surface area can be made larger by making one surface to be a convex one and an other surface to be a concave surface corresponding to the convex surface, in a similarly manner as in the embodiment mentioned above.

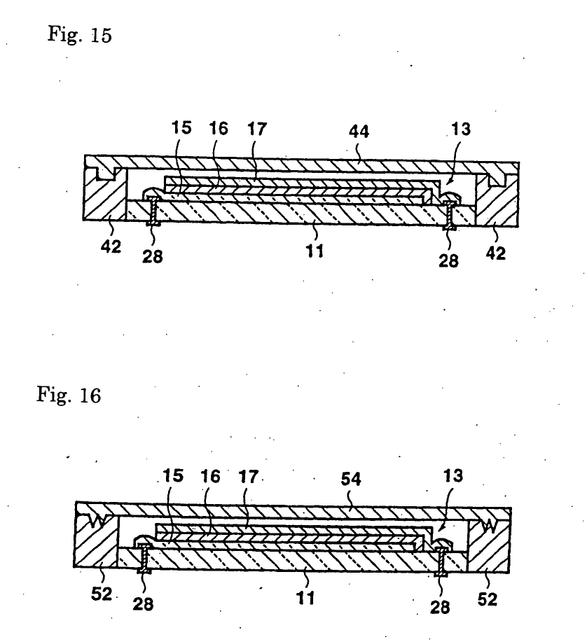

FIG. 15 is a cross section showing a modified example of the organic electroluminescent light emitting device shown in FIG. 12 and FIG. 13. In this light emitting device, a metal frame 42 is provided as having a thickness larger than that of substrate 11 and forming a side wall around the substrate 11. On an upper end of the metal frame 42, a concave portion is formed. On the other hand, the metal sealing cap 44 is formed to be a flat board, having a convex portion formed on the lower surface of the periphery of the flat board portion of the metal sealing cap 44. The convex portion of the metal sealing cap 44 fits with the concave portion of the metal frame 42, so that the both parts are joined to form non moisture permeable structure.

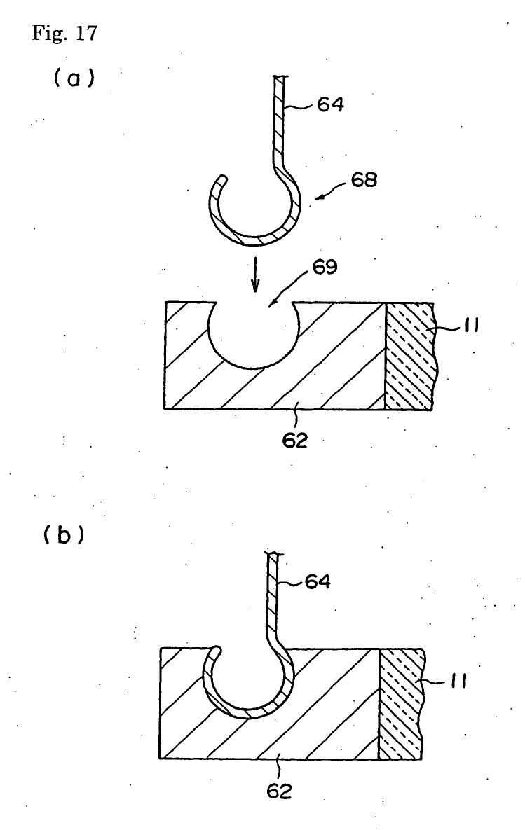

FIG. 16 is a cross section showing another modification of the organic electroluminescent light emitting device shown in FIG. 15. In this light emitting device, the lower surface of the periphery portion of the metal sealing cap 54 is provided with a convex surface having two chevron like projection is provided, while the upper surface of the metal frame 52 is provided with two valley shape concave surface corresponding with the above mentioned convex surface. The convex portion of the metal seal caps 44 fits with the concave portion of the metal frame 42, so that the both parts are joined in non moisture permeable way.

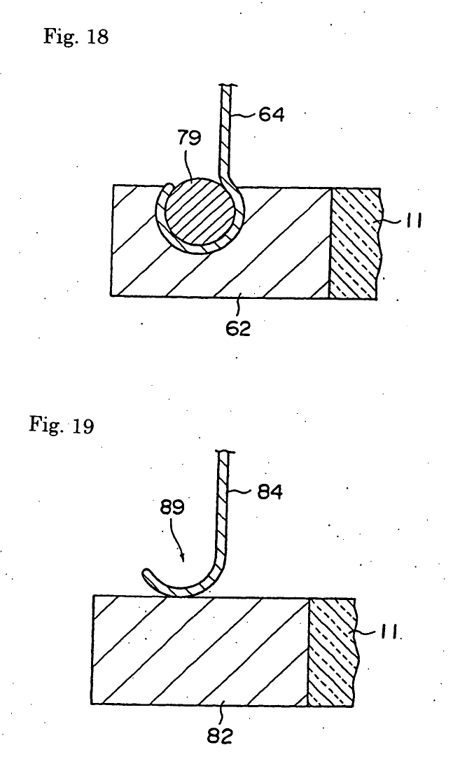

A metal sealing cap and a metal frame can be joined in non moisture permeable way by a mechanical joining. FIG. 17 is a drawing for explaining an example of a mechanical joining method of a metal sealing cap and a metal frame. As shown in FIG. 17(a), the metal sealing cap is processed to form an elastic region 68 with metal elasticity on the periphery. On the other hand, a groove 69 having a corresponding shape with the elastic region is formed on the metal frame 62. As shown in FIG. 17(b), the metal seal cap 64 can be joined to the metal frame 62 in non moisture permeable way by fitting the elastic region 68 of the metal seal cap 64 into the groove 69 of the metal frame 62 with a mechanical joining method.

FIG. 18 is a drawing for explaining a further different example of a method for joining the metal sealing cap to the metal frame in the manufacturing of the organic electroluminescent light emitting device shown in FIG. 17. Here, in order to make the moisture amount minimum intruding through the joined region of metal sealing cap 64 and metal frame 62, an O-ring 79 composed of an elastic material such as rubber, for example, is provided to press the elastic region 68 into the groove of the metal frame 62.

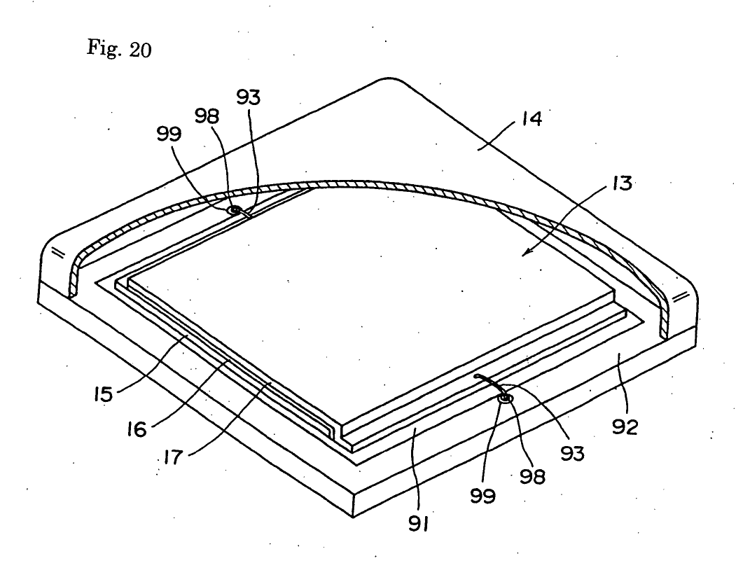

FIG. 19 is a drawing for explaining a further different example of a joining method of the metal sealing cap to the metal frame. Here, the metal sealing cap 84 is processed to form a welding area 89 on its periphery. A contact area between the welding area 89 of the metal sealing cap 84 and the metal frame 82 is welded by ultrasonic welding, for example.

Also in the present embodiment, it is possible to make the space formed by a translucent non moisture permeable substrate, a metal frame, and a metal sealing cap to be a vacuum space or a space filled with an inert gas. For this purpose, it is only to join the metal sealing cap to the metal frame in the vacuum or in the inert gas atmosphere.

As mentioned above, by joining the metal sealing cap to the metal frame in a short time and at a low temperature after forming the light emitting laminated body 13, the organic electroluminescent light emitting device can be produced, which hardly changes the light emitting characteristics with time.

Here, the parts or materials composing the above mentioned organic electroluminescent light emitting device are similar to those in the first embodiment, so the details are omitted.

FIG. 20 is a perspective view, with a part is cut, showing the fifth embodiment of the organic electroluminescent light emitting device according to the present invention. Here, in the drawing, the same symbols are assigned to the same portions as those in the embodiments mentioned above. As shown in FIG. 20, electrical connecting terminals 98, which are connected with each electrode layer 15 and 17 of the light emitting laminated body 13, are installed in the metal frame 92 by penetrating the metal frame through insulating material 99. The surface contamination of the non moisture permeable translucent substrate 91 during the install process of electrical connecting terminal is prevented by installing electrical connecting terminals 99 in the metal frame 92. Each of the electrode layers 15 and 17 is connected electrically to each electrical connecting terminal 98 by bonding wires 93.

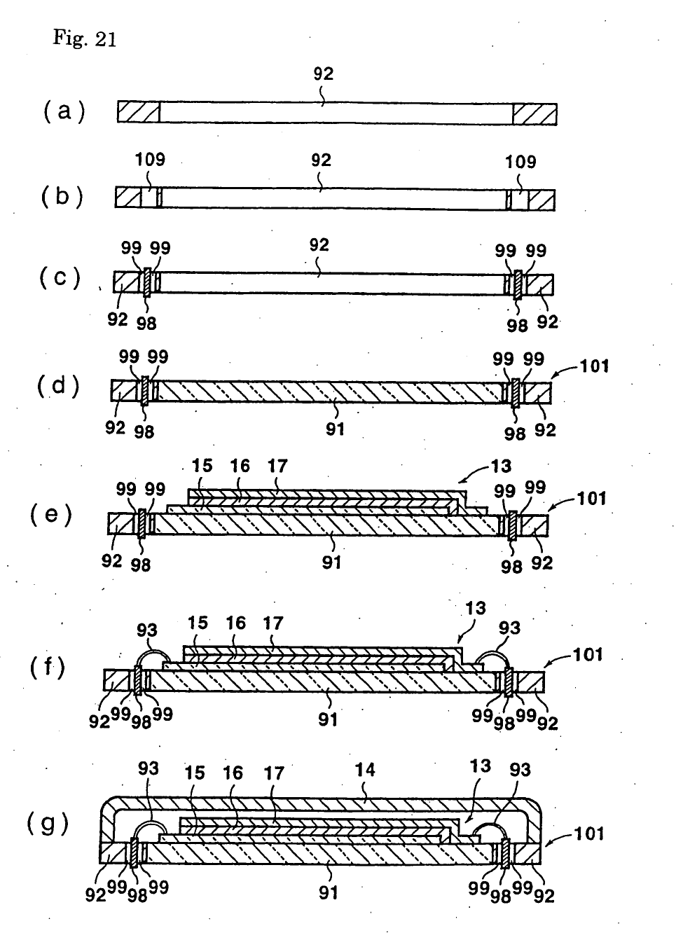

FIG. 21 is a drawing for explaining a method for manufacturing the organic electroluminescent light emitting device shown in FIG. 20. First, a metal frame 92 is prepared as shown in FIG. 21(a). In the next, holes 109 for installing electrical connecting terminals are provided on the metal frame 92, as shown in FIG. 21(b). Then, as shown in FIG. 21(c), connecting terminals 98 are installed in the hole 109 through insulating materials 99 such as flit glass. The connecting terminals 98 may also be deposited with flit glass on the periphery in advance, and be inserted into the hole 109 to weld with flit glass 99 and metal frame 92. Instead of flit glass, a heat curing type adhesive may be used. Then, as shown in FIG. 21(d), a metal frame 92, installed with electrical connecting terminal 98, is joined in non moisture permeable manner to the periphery of the non moisture permeable translucent substrate 91. In the organic electroluminescent light emitting device shown in FIG. 21, the metal frame 92 and the non moisture permeable translucent substrate 91 are joined together in non moisture permeable manner by welding. Thus, a light emitting element substrate 101 including the non moisture permeable translucent substrate 91, the metal frame 92, and the electrical connecting terminal 98 etc. are prepared.

In the next, as shown in FIG. 21(e), light emitting laminated body 13 is formed by laminating a translucent electrode layer 15, an organic light emitting material layer 16, and an electrode layer 17 in this order on one surface of the non moisture permeable translucent substrate 91 of the light emitting element substrate 101. As shown in FIG. 21(f), each of the translucent electrode layers 15 and 17 is connected electrically with each of the electrical connecting terminals 98 by bonding wires 93.

Then, as shown in FIG. 21(g), a metal sealing cap 14 is installed on the surface of the light emitting substrate 101 on the side of which the light emitting laminated body 13 is formed, so as not to contact with the light emitting laminated body 13. The organic electroluminescent light emitting device shown in FIG. 9 is thus completed by joining the periphery of the metal sealing cap 14 to the metal frame 92 in non moisture permeable manner.

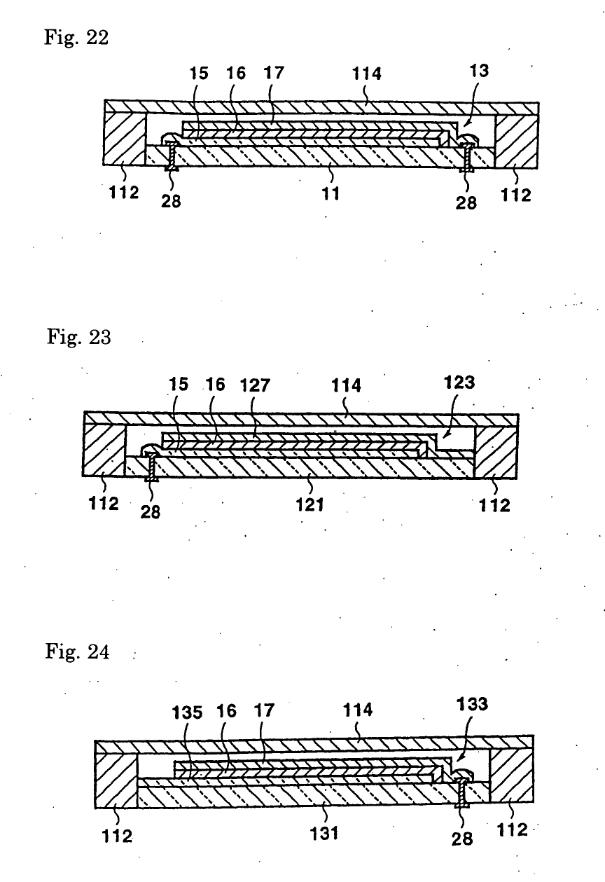

FIG. 22 is a cross section showing a further different modification to the embodiment of the organic electroluminescent light emitting device according to the present invention. The organic electroluminescent light emitting device has a similar structure to the organic electroluminescent light emitting device shown in FIG. 12, except that the metal frame 112 has a different shape and that a planar metal protection plate 114 is used.

FIG. 23 is a cross section showing a further different modification to the embodiment of the organic electroluminescent light emitting device according to the present invention. The organic electroluminescent light emitting device has a similar structure to the organic electroluminescent light emitting device shown in FIG. 22 except that the manner with which the electrical connecting terminal for supplying electric energy to the electrode layer 127 of the organic EL emitting laminated body 123 is installed. That is, the translucent electrode layer 15 of the light emitting laminated body 123 is electrically connected with the electrical connecting terminal 28 and the electrode layer 127 is electrically connected with metal frame 112. By electrically connecting the electrode layer 127 with the metal frame 112, the metal frame 112 or metal sealing cap 114 can be used as electrical connecting terminals for the electrode layer 127.

FIG. 24 is a cross section showing a further different modification to the embodiment of the organic electroluminescent light emitting device according to the present invention. The organic electroluminescent light emitting device has a similar structure to the organic electroluminescent light emitting device shown in FIG. 22 except that the manner with which the electrical connecting terminal for supplying electric energy to the translucent electrode layer 135 of the light emitting laminated body 133 is installed. That is, the metal frame 112 or metal sealing cap 114 can be used as electrical connecting terminals of the translucent electrode layer 135 by electrically connecting the electrode layer 17 of the light emitting laminated body 133 with electrical connecting terminal 28, and by electrically connecting the translucent electrode layer 135 with the metal frame 112.

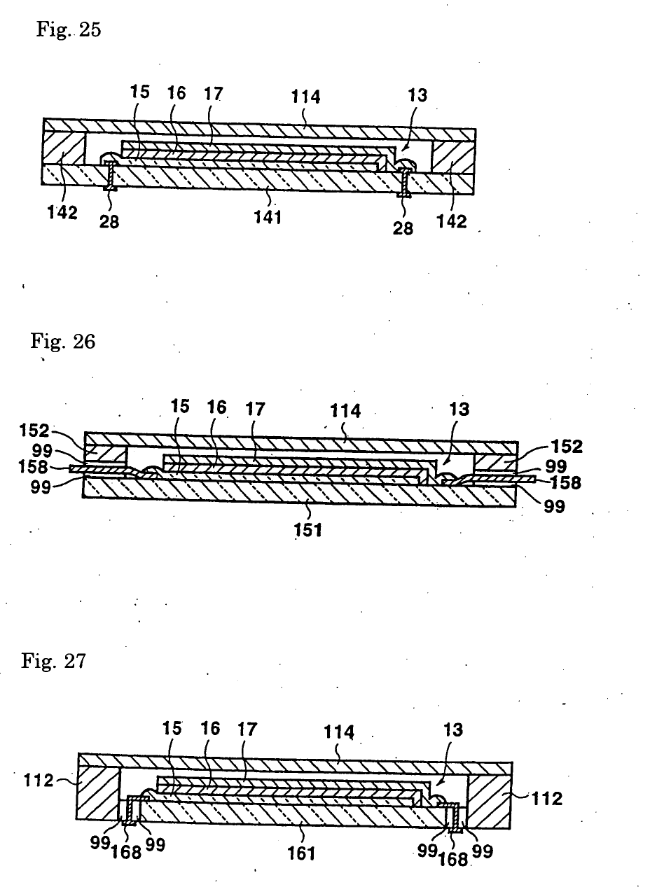

FIG. 25 is a cross section showing a further different modification to the embodiment of the organic electroluminescent light emitting device according to the present invention. The organic electroluminescent light emitting device has a similar structure to the organic electroluminescent light emitting device shown in FIG. 22 except that the non moisture permeable translucent substrate 141 and the metal frame 142 have a different shape from those in FIG. 22. That is, the metal frame 142 is joined to the vicinity of the periphery of non moisture permeable translucent substrate 141 in non moisture permeable manner. Such construction has an advantage that the pressure is easily applied to the joined portion when the non moisture permeable translucent substrate 141 is joined to the metal frame 142. Besides, there is also an advantage that when the metal sealing cap 114 is joined to the metal frame 142 with pressure being applied, the non moisture permeable translucent substrate 141 and the metal frame 142 are hard to be separated from each other.

FIG. 26 is a cross section showing a further different modification to the embodiment of the organic electroluminescent light emitting device of the present invention. The organic electroluminescent light emitting device has a similar structure to the organic electroluminescent light emitting device shown in FIG. 25 except that the manner with which the electrical connecting terminal 158 for supplying electric energy to the translucent electrode layers 15 and 17 of the light emitting laminated body 13 is installed, and that the method for joining the non moisture permeable translucent substrate 151 to the metal frame 152 is different from that shown in FIG. 25. That is, the metal frame 152 is joined by an insulating material flit glass 99 to the vicinity of the periphery of non moisture permeable translucent substrate 151 in non moisture permeable manner. When the non moisture permeable translucent substrate 151 is joined to the metal frame 152, the connecting terminal 158 is installed so as to penetrate the joined portion through an insulating material such as flit glass.

FIG. 27 is a cross section showing a further different modification to the embodiment of the organic electroluminescent light emitting device of the present invention. The organic electroluminescent light emitting device has a similar structure to the organic electroluminescent light emitting device shown in FIG. 26 except that the electrical connecting terminal 168 is installed at different portion.

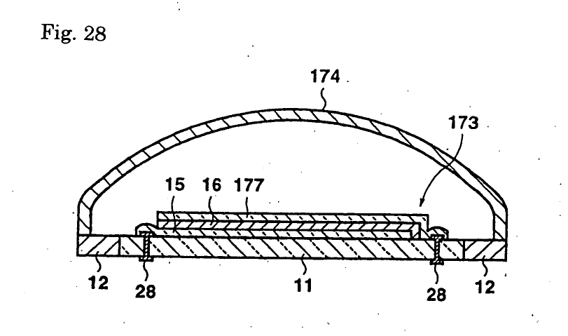

FIG. 28 is across section showing a further different modification to the embodiment of the organic electroluminescent light emitting device of the present invention. In the organic electroluminescent light emitting device, the light emitting laminated body 173 has electrode layers 15 and 177 made of translucent electrodes. A metal sealing cap 174 has an inner surface of a spherical shape. With the configuration, the light emitted from the organic light emitting material layer 16 of the light emitting laminated body 173 is reflected by the metal sealing cap 174, and thus the directivity of the light emitted from the organic electroluminescent light emitting device can be adjusted. The metal sealing cap 174 may have any other curved shape to adjust the directivity of the light emitted from the organic electroluminescent light emitting device. Thus, it is preferable that the metal sealing cap 174 has an inner surface partly including a spherical surface, an ellipsoid surface or a parabolic surface.

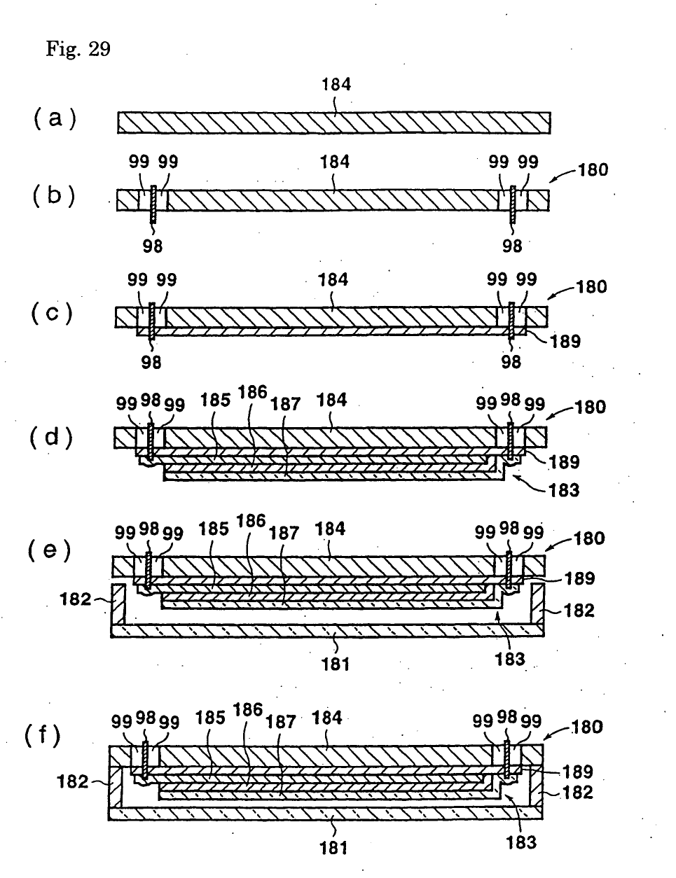

FIG. 29 is a drawing for explaining a method for manufacturing the organic electroluminescent light emitting device which is the sixth embodiment of the present invention. First, a metal plate 184 shown in FIG. 29(a) is prepared. In the next, as shown in FIG. 29(b), electrical connecting terminals 98 are installed by penetrating the metal plate 184 through an insulating material 99, thereby forming a metal plate with connecting terminals 180.

Then, as shown in FIG. 29(c), an insulating layer 189 is formed on one surface of the metal plate 180. As examples of materials for the insulating layer 189, polyimide resin, acrylic resin, and glass are used. Then, as shown in FIG. 29(d), light emitting laminated body 183 is produced by laminating an electrode layer 185, an organic light emitting material layer 186, and a translucent electrode layer 187, in this order, on the surface of the insulating layer 189. Each of the electrode layers 185 and 187 is electrically connected with each of the electrical connecting terminals 98 by being formed so as to contact with each of the electrical connecting terminals 98.

In the next, as shown in FIG. 29(e), a non moisture permeable translucent substrate 181 is prepared. A metal frame 182 is joined to the vicinity of the periphery of the substrate 181 in non moisture permeable manner. Then, as shown in FIG. 29(f), a metal frame 182 which is joined to the substrate 181 is arranged to face the surface of the metal plate 180, where light emitting laminated body 183 is formed. The metal frame 182 fixed to the substrate 181 is joined to the periphery of the metal plate 184 in non moisture permeable manner, so as not to contact with the light emitting laminated body 183. Here, in the light emitting laminated body 183, the layers are laminated in the reverse direction to that in the organic electroluminescent light emitting device shown in FIG. 12. That is, cathode 185, organic light emitting material layer 186, and translucent anode layer 187 are laminated on the metal plate 184 in this order.

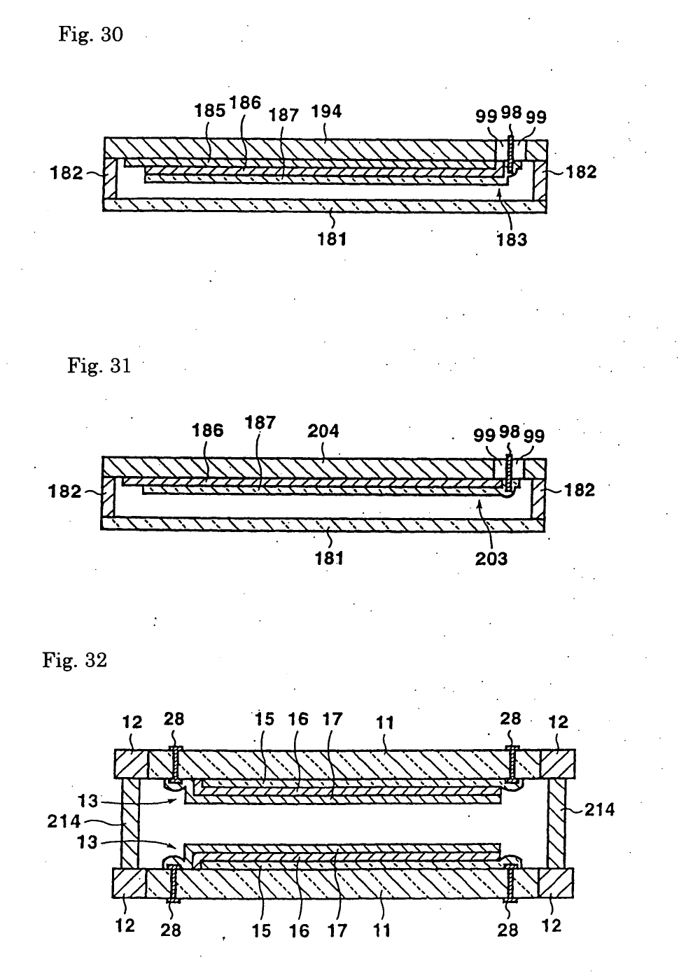

FIG. 30 is a cross section showing a modification to the above embodiment of the organic electroluminescent light emitting device shown in FIG. 29. In the organic electroluminescent light emitting device, the metal plate 194 is used as an electrical connecting terminal of the electrode layer 185 by directly forming an electrode layer 185 of the light emitting laminated body 183 on a surface of a metal plate 194.

FIG. 31 is a cross section showing a further different modification to the embodiment of the organic electroluminescent light emitting device shown in FIG. 29. In the organic electroluminescent light emitting device, a light emitting laminated body 203 having an organic light emitting material layer 186 and an electrode layer 187 are formed on a surface of a metal plate 204. Here, the organic light emitting material layer 186 is located on the side of the metal plate. The metal plate 204 functions as another electrode layer and an electrical connecting terminal of the light emitting laminated body 203. With the configuration that the metal plate 204 functions as the electrode and the electrical connecting terminal of the light emitting laminated body 203, the structure of the organic electroluminescent light emitting device can be simplified.

Here, in the present invention, the number of the light emitting laminated body formed on the non moisture permeable translucent substrate or on the metal plate are not limited to a particular one. A plurality of light emitting laminated body may be aligned and formed on a non moisture permeable translucent substrate or on a metal plate to construct a display device.//

FIG. 32 is a cross section showing one example of an organic electroluminescent light emitting device provided with a plurality of light emitting laminated bodies. The present organic electroluminescent light emitting device is fabricated as follows. First, two set of non moisture permeable translucent substrates 11 are prepared. Metal frames 12 are joined on the each of the peripheries of the substrates 11 in non moisture permeable manner. Electrical connecting terminals 28 are installed to the substrates 11 by penetrating them. An light emitting laminated body 13 having an organic light emitting material layer 16 and electrode layers 15 and 17 are formed on a surface of each substrates 11. Each of the light emitting laminated body 13 are formed by laminating a translucent electrode layer, an organic light emitting material layer, and an electrode layer on the translucent plate 11 in this order. Then, two set of substrates 11 are arranged so that the light emitting laminated bodies 13 are facing to each other. The metal frames 12 of each substrate are connected in non moisture permeable manner with a metal seal means 214. With the organic electroluminescent light emitting device thus obtained, light is emitted from both sides of the light emitting device, and different displays are possible on both sides of the device.

1. An organic electroluminescent light emitting device comprising:
a translucent insulating substrate,
a light emitting laminated body provided on the translucent insulating substrate including an organic EL light emitting layer and an electrode layer laminated thereon,
a sealing cap joined to the translucent insulating substrate to form a space covering the light emitting laminated body, and
electrically connecting terminals which penetrate the sealing cap or the translucent insulating substrate and supply electric power to the electrode layers included in the light emitting laminated body,
wherein the electrical connecting terminals are led outside without passing through the joined portion between the translucent insulating substrate and the sealing cap.

2. An organic electroluminescent light emitting device according to claim 1, wherein the substrate is joined to the sealing cap using an adhesive.

3. An organic electroluminescent light emitting device according to claim 2, wherein the adhesive is composed of an acrylic or an epoxy adhesive, which is set at a room temperature or cured by ultraviolet ray.

4. An organic electroluminescent light emitting device according to claim 3, wherein the light emitting laminated body comprises the first and the second electrode layers which are laminated above and below the organic EL light emitting layer, a plurality of the electrical connecting terminals are provided on the substrate or on the sealing cap, and the first and the second electrode layers are connected with each of the plurality of the electrical connecting terminals.

5. An organic electroluminescent light emitting device according to claim 1, wherein the electrical connecting terminals are made of metal and are fixed in the through hole formed on the substrate by the adhesive.

6. An organic electroluminescent light emitting device according to claim 1, wherein the substrate is a glass substrate and the electrical connecting terminals are fixed by melting a part of the glass substrate.

7. An organic electroluminescent light emitting device according to claim 1, wherein the electrical connecting terminals are metal plates provided on opposite edges of the substrate.

8. An organic electroluminescent light emitting device comprising:
a translucent insulating substrate on the periphery of which a metal frame is joined,
a light emitting laminated body composed of a first electrode layer, an organic EL light emitting layer, and a second electrode layer, which are laminated in this order,
a sealing metal cap which is joined to the metal frame to form a space covering the light emitting laminated body,
and electrical connecting terminals which penetrate the sealing cap or the translucent insulating substrate and supply electric power to each electrode layer of the light emitting laminated layer,
wherein the electrical connecting terminals are led out without passing through the joined portion between the substrate and the sealing cap.

9. An organic electroluminescent light emitting device according to claim 8, wherein the metal frame forms a chassis with the insulating substrate at a bottom by forming walls around the insulating substrate, and by joining the sealing cap to the top end of the metal frame, and a non moisture permeable sealed space is formed together with the chassis.

10. An organic electroluminescent light emitting device according to claim 9, wherein the sealing cap is joined to the metal frame by fitting a convex portion formed on one of joining surfaces to a concave portion formed on the other of the joining surfaces.

11. An organic electroluminescent light emitting device according to claim 8, wherein the sealing cap is joined to the metal frame by fitting an elastic portion formed on the periphery of the sealing cap into a groove which is formed on the joining surface of the metal frame to have a corresponding shape to the elastic portion.

12. An organic electroluminescent light emitting device according to claim 11, wherein an 0-ring for sealing is inserted inside the groove having the corresponding shape to the elastic portion.

13. An organic electroluminescent light emitting device according to claim 8, wherein the sealing cap is joined to the metal frame by welding while the welding portion formed on the periphery of the sealing cap is in contacting with the joining surface of the metal frame.

14. An organic electroluminescent light emitting device according to claim 8, wherein the translucent insulating substrate is a glass substrate, and the electrical connecting terminals are fixed by melting a part of the glass substrate.

15. An organic electroluminescent light emitting device comprising:
a non moisture permeable translucent substrate,
a metal frame joined to the periphery of the translucent substrate,
a pair of electrical connecting terminals penetrating the metal frame through an insulating material,
a light emitting laminated body provided on one surface of the non moisture permeable translucent substrate, which is composed of an organic light emitting material layer and a pair of electrode layers laminated on both side of the organic light emitting material layer,
an interconnection means, which connects each of the pair of electrode layers of the light emitting laminated body with each of the pair of electrically connecting terminals, and
a metal sealing cap, which is joined to the metal frame in non moisture permeable manner on the side of the translucent substrate where the light emitting laminated body is provided, so as not to contact with the light emitting laminated body.

16. An organic electroluminescent light emitting device comprising:
a non moisture permeable translucent substrate on the periphery of which a metal frame is joined,
one or plurality of electrical connecting terminals which penetrate the substrate or a joined portion of the substrate with the metal frame,
a light emitting laminated body, which is provided on a surface of the substrate and is composed of an organic light emitting material layer and a pair of electrode layers laminated on both sides of the organic light emitting material layer those are, and
a metal sealing cap which is joined to the metal frame with in non moisture permeable manner construction on the surface of the substrate where the light emitting laminated body is provided, so as not to contact with the light emitting laminated body,
wherein a chassis is formed with the substrate at its bottom and with a wall with the metal frame around the substrate, and wherein each of the pair of electrode layers forming the light emitting laminated body are respectively connected with the electrical connecting terminals.

17. An organic electroluminescent light emitting device comprising:
a non moisture permeable translucent substrate on the periphery of which a metal frame is joined,
one or plurality of electrical connecting terminals which penetrate the substrate,
a light emitting laminated body, which is provided on a surface of the substrate and is composed of an organic light emitting material layer and a pair of electrode layers laminated on both sides of the organic light emitting material layer those are, and
a metal sealing cap which is joined to the metal frame with in non moisture permeable manner on the surface of the substrate where the light emitting laminated body is provided, so as not to contact with the light emitting laminated body,
wherein a chassis is formed with the substrate at its bottom and with a wall with the metal frame around the substrate, and wherein one of the pair of electrode layers forming the light emitting laminated body is connected with the electrical connecting terminals, while the other electrode layers is connected with the metal frame.

18. An organic electroluminescent light emitting device comprising:
a metal substrate,
one or a plurality of electrical connecting terminals which penetrate the metal substrate through insulating material,
an light emitting laminated body composed of an organic light emitting material layer and laminated electrode layers laminated thereon, and
a non moisture permeable translucent plate, which is provided on a surface of the metal substrate where the light emitting laminated body is formed and to the periphery of which a metal frame is joined with non moisture permeable construction so as not to contact with the light emitting laminated body,
wherein the electrode layer laminated on the organic light emitting material layer is connected to the electrical connecting terminal.

19. An organic electroluminescent light emitting device according to claim 18, wherein the organic light emitting material layer is provided with a pair of electrode layers which are laminated above and under the organic light emitting material layer and one of which is connected with the electrical connecting terminal, the other of which is connected with the metal plate.

20. An organic electroluminescent light emitting device according to claim 18, wherein an electrode layer is laminated on one surface of the organic light emitting material layer, the electrode layer is connected with the electrical connecting terminal, and the other surface of the organic light emitting material layer is connected electrically by contacting with the metal plate.

21. An organic electroluminescent light emitting device according to claim 18, wherein the non moisture permeable translucent substrate is a glass plate.

22. An organic electroluminescent light emitting device comprising:
a first and a second non moisture permeable translucent substrate with metal frame joined on the periphery,
one or plurality of electrical connecting terminals penetrate the substrates,
a light emitting laminated body composed of a pair of electrode layers and an organic light emitting material layer laminated between the pair of electrode layers, which are formed on one surface of the first and the second non moisture permeable substrates, and
a metal sealing cap which joins the first and the second non moisture permeable substrates, so as to make surfaces of the first and the second non moisture permeable translucent substrate where the light emitting laminated body face with each other,
wherein the electrode layers forming the light emitting laminated body are connected to each of the electrical connecting terminals respectively.

23. A manufacturing method for an organic electroluminescent light emitting device comprising steps of:
joining a metal frame on a periphery of a non moisture permeable translucent substrate,
fixing a plurality of electrically connecting terminals to the metal frame or the translucent substrate in a state electrically insulated there from,
making the plurality of electrically connecting terminals penetrate through the metal frame or the translucent substrate,
forming a light emitting laminated body on a surface of the substrate having an organic light emitting material layer and a plurality of electrode layers,
connecting the plurality of electrode layers with the electrical connecting terminals or the metal frame, and
joining a metal sealing cap or a metal protection plate to the surface of the translucent substrate with non moisture permeable construction on which the light emitting laminated body is formed so that the metal caps or the protection plate may not contact with the light emitting laminated body.

24. A manufacturing method for an organic electroluminescent light emitting device comprising steps of:
preparing a non moisture permeable translucent substrate having a metal frame joined on a peripheral portion,
preparing a metal plate having one or a plurality of electrical connecting terminals which penetrate the metal plate through an insulating material,
forming an light emitting laminated body composed of an organic light emitting material layer and electrode layers laminated thereon on one surface directly or through an insulating layer,
connecting the electrode layers forming the light emitting laminated body with the electrical connecting terminals, and
joining the metal frame joined to the non moisture permeable translucent substrate to a peripheral portion of the metal plate so as not to contact with the light emitting laminated body.

25. A method for manufacturing an organic electroluminescent light emitting device according to claim 23, wherein the metal frame is joined to the metal sealing cap or the metal protection plate by welding, applying ultrasonic energy, or a mechanical joining.

26. A manufacturing method for an organic electroluminescent light emitting device according to claim 23, wherein the glass plate is used for the non moisture permeable translucent substrate.
